(19) United States
(12) Patent Application Publication
(10) Pub. No.: US 2009/0152241 A1
(43) Pub. Date: Jun. 18, 2009

(54) PLASMA ETCHING APPARATUS AND PLASMA ETCHING METHOD

(76) Inventors: Go MIYA, Tokyo (JP); Junichi TANAKA, Tokyo (JP); Seiichiro KANNO, Tokyo (JP); Naoshi ITABASHI, Tokyo (JP); Hiroshi AKIYAMA, Kudamatsu-shi (JP); Kouhei SATOU, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/390,231

(22) Filed: Feb. 20, 2009

Related U.S. Application Data
(63) Continuation of application No. 11/682,382, filed on Mar. 6, 2007.

(30) Foreign Application Priority Data
Nov. 9, 2006 (JP) 2006-303470

(51) Int. Cl. H01L 21/306

(52) U.S. Cl. 216/60

(57) ABSTRACT

The invention provides a method and apparatus for performing plasma etching to form a gate electrode on a large-scale substrate while ensuring the in-plane uniformity of the CD shift of the gate electrode. The present invention measures a radical density distribution of plasma in the processing chamber, feeds processing gases into the processing chamber through multiple locations and controls either the flow rates or compositions of the respective processing gases or the in-plane temperature distribution of a stage on which the substrate is placed, or feeds processing gases into the processing chamber through multiple locations and controls both the flow rates or compositions of the processing gases and the in-plane temperature distribution of the stage on which the substrate is placed.

### CROSS REFERENCE TO RELATED APPLICATION

This application is a Continuation of U.S. application Ser. No. 11/682,382, filed Mar. 6, 2007, which claims priority from Japanese Patent Application No. 2006-303470 filed on Nov. 9, 2006, the contents of which are incorporated herein by reference.

### BACKGROUND OF THE INVENTION

1. Field of the Invention

The present invention relates to the art of plasma etching, and more specifically, relates to a plasma etching apparatus and a plasma etching method for etching a substrate having superior in-plane uniformity of CD shift distribution.

2. Description of the Related Art

Japanese Patent Application Laid-Open Publication No. 2005-56914 (patent document 1) discloses a prior art plasma etching apparatus in which a plurality of light receiving means for receiving plasma emission is disposed in the radial direction at the upper portion of the processing apparatus for measuring the radical density in the plasma, and based on the results, gases having different compositions are fed through a plurality of gas inlets disposed in the radial direction so as to control the radical density distribution in the plasma, and to thereby improve the in-plane uniformity of the substrate.

However, recently in the art of gate etching in which a processing accuracy in the order of nanometers is demanded throughout the whole surface of the large-diameter substrate, it is desirable to perform measurement at multiple points in the vacuum processing chamber, and in order to do so, a large number of light receiving units must be disposed. Such system requires a large installation space, and it became evident that it is difficult to apply such prior art teachings.

With respect to the problems mentioned above, the present inventors have proposed in Japanese Patent Application No. 2005-136248 (patent document 2) an art of inserting a light receiving unit in an area in which plasma exists in the vacuum processing chamber, rotating the light receiving unit to receive plasma emission, and obtaining the radical density distribution. However, patent document 2 does not disclose a means for reflecting the result of the density distribution data obtained from the plasma emission to the etching process, and therefore, it is not sufficient to overcome the prior art problems mentioned above.

### SUMMARY OF THE INVENTION

The present invention aims at solving the problems of the prior art, and provides a plasma etching apparatus and a plasma etching method for accurately measuring the plasma emission distribution within the vacuum processing chamber, and reflecting the result thereof to the plasma etching process so as to realize a uniform in-plane distribution of CD shift of the substrate.

The present invention applies the following means to solve the prior art problems.

The object of the present invention is achieved by a plasma etching apparatus comprising a vacuum processing chamber for subjecting a substrate to plasma processing, gas inlets provided at least at two locations for feeding processing gas into the vacuum processing chamber, a substrate stage for holding the substrate and having disposed therein a temperature control means for controlling the temperature of at least two locations, an electromagnetic wave supplying means for supplying electromagnetic waves into the vacuum processing chamber, a plasma emission distribution measurement system for measuring the distribution of plasma emission near a surface of the substrate from a side direction, a means for computing a radical distribution in the plasma based on the plasma emission distribution measurement system, and a means for controlling both a composition or a flow rate of the processing gas fed through the gas inlets provided at two locations and the temperature of at least two locations in the substrate stage of the substrate based on the radical distribution computed in advance by the means for computing radical distribution and the measurement results of CD shift distribution.

Further, the present object is achieved by providing a plasma etching apparatus further comprising a means for computing the radical distribution in the plasma during the plasma etching process, and controlling based on the computed radical distribution either the respective compositions or flow rates of the processing gases fed through the gas inlets provided at two locations, or the temperature distribution of the substrate stage of the substrate.

Further, the present object is achieved by providing a plasma etching method for etching a substrate using the above plasma etching apparatus, comprising the steps of measuring a radical density distribution of at least one radical and a CD shift distribution during the etching process by performing at least two etching processes in advance with the flow rates of processing gases varied, storing the conditions of the etching processes, the radical density distribution and the CD shift distribution in a database, computing a relational expression of the radical density distribution for the at least one radical and the CD shift distribution, computing a processing condition to realize a uniform CD shift using the relational expression, and computing a control parameter of the etching process so as to realize the processing condition computed to realize a uniform CD shift, wherein the etching process of the substrate is performed using the computed control parameter.

Further, the present object is achieved by a plasma etching method further comprising measuring the radical density distribution of said at least one type of radical during the etching process, and computing during the etching process the control parameter of the etching process so as to realize the processing condition computed to realize a uniform CD shift, wherein the etching process of the substrate is performed using the computed control parameter.

Moreover, the present object is achieved by a plasma etching method wherein said control parameter for the etching process for realizing the processing condition computed so a to realize a uniform CD shift is at least either the compositions or flow rates of the processing gases fed from at least two locations, or the set temperatures of the temperature control means disposed at least at two locations for controlling the temperature distribution of the substrate.

The present invention having the arrangements mentioned above provides a plasma etching apparatus and a plasma etching method capable of measuring the density distribution of various radicals in the plasma, and based on the measured results, controlling either the compositions or flow rates of processing gases fed through gas inlets disposed at two locations or the temperature distribution of the substrate stage so as to control the radical distribution in the plasma, and realizing a uniform in-plane CD shift distribution.

### BRIEF DESCRIPTION OF THE DRAWINGS

FIG. 1 is a configuration diagram of the plasma etching apparatus used in the first embodiment of the present invention;

FIG. 2 is a flowchart showing the flow of the process according to the first embodiment of the present invention;

FIG. 3 is a density distribution diagram of O radicals and SiClₓ radicals which is optimized by applying the first embodiment of the present invention and which is not optimized by applying the first embodiment of the present invention;

FIG. 4 is a CD shift distribution diagram which is not optimized by applying the first embodiment of the present invention and which is not optimized by applying the first embodiment of the present invention;

FIG. 5 is a configuration diagram of the plasma etching apparatus used in the second embodiment of the present invention;

FIG. 6 is a flowchart showing the flow of the process according to the second embodiment of the present invention;

FIG. 7 is a configuration diagram of the plasma etching apparatus used in the third embodiment of the present invention;

FIG. 8 is a flowchart showing the flow of the process according to the third embodiment of the present invention;

FIG. 9 is an enlarged view of the portion near the light receiving unit of the plasma emission distribution measurement system used in the fourth embodiment of the present invention;

FIG. 10 is an enlarged view of the portion near the light receiving unit of the plasma emission distribution measurement system used in the fifth embodiment of the present invention;

FIG. 11 is a top view of the plasma etching apparatus used in the sixth embodiment of the present invention; and

FIG. 12(a) is a density distribution diagram of O radicals obtained by applying the sixth embodiment of the present invention, and FIG. 12(b) is an emission peak intensity distribution of O radicals.

### DETAILED DESCRIPTION OF THE PREFERRED EMBODIMENTS

### Embodiment 1

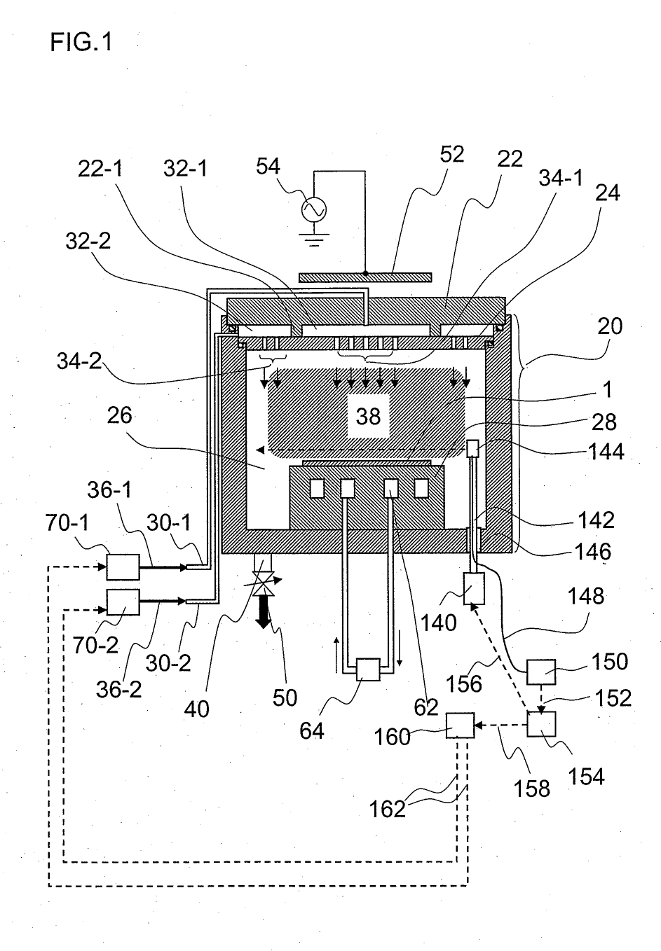

Now, a first embodiment in which the present invention is applied to an etching process for forming a gate electrode (hereinafter referred to as gate etching) is described with reference to FIGS. 1 through 4. FIG. 1 is a cross-sectional view showing the structure of a UHF-ECR (ultra high frequency—electron cyclotron resonance) plasma etching apparatus to which the first embodiment of the present invention is applied. In FIG. 1, a processing chamber lid 22 is disposed on top of a substantially cylindrical processing chamber side wall 20 by which a vacuum processing chamber 26 is defined, and in the vacuum processing chamber 26 is disposed a substrate stage 28 for holding a substrate 1. Two lines of processing gasses composed of a center-side gas line 70-1 and a circumference-side gas line 70-2 are introduced to the vacuum processing chamber 26. Each gas line is composed for example of a gas supply means such as a gas cylinder (not shown), a flow rate control means (not shown) for controlling the flow rate of each gas, and a valve (not shown) for outputting or stopping the flow of each gas, and the lines are capable of outputting the desired gas at a desirable flow rate or stopping the same.

A first processing gas 36-1 led to a first gas feed pipe 30-1 via the center-side gas line 70-1 is supplied to a center-side space 32-1 formed between the processing chamber lid 22 and a shower head plate 24. A center-side gas feed area 34-1 composed of multiple holes is formed at the center of the shower head plate 24 disposed at a position opposing to the substrate 1, through which the first processing gas 36-1 is fed into the vacuum processing chamber 26. Similarly, a second processing gas 36-2 guided via the second gas feed pipe 30-2 is supplied to a circumference-side space 32-2 formed between the processing chamber lid 22 and the shower head plate 24. A circumference-side gas feed area 34-2 composed of multiple holes is formed at the outer side of the center-side gas feed area 34-1 on the shower head plate 24, through which the second processing gas 36-2 is fed into the vacuum processing chamber 26.

Moreover, a circumferential projection 22-1 is formed on the lower surface of the processing chamber lid 22, which adheres tightly to the upper surface of the shower head plate 24 and separates the center-side space 32-1 from the circumference-side space 32-2, so as to prevent the first processing gas 36-1 and the second processing gas 36-2 from mixing before being fed into the vacuum processing chamber 26.

By the above arrangement, the first processing gas 36-1 and the second processing gas 36-2 having different flow rates and different compositions (if the gas is a mixed gas composed of a plurality of gases, the flow rate of each gas) are fed respectively into the vacuum processing chamber 26 through the center-side gas feed area 34-1 and the circumference-side gas feed area 34-2. A substrate stage 28 is disposed in the vacuum processing chamber 26, on which a substrate 1 to be processed is attached via electrostatic chuck. Multiple lines of fluid passages 62 are formed at various radial positions within the substrate stage 28, and by controlling the temperature of the fluid circulated therethrough via a circulator 64, it becomes possible to control the temperature of the substrate 1.

A portion of the first processing gas 36-1 and the second processing gas 36-2 and volatile products generated by the reaction during the plasma etching process are evacuated through an exhaust port 40. A vacuum pump (not shown) is connected to the end of the exhaust port 40, by which the pressure within the vacuum processing chamber 26 is reduced to approximately 1 Pa (Pascal).

An antenna 52 is disposed above the processing chamber lid 22, through which electromagnetic waves are fed from an UHF power supply 54 through the processing chamber lid 22 and the shower head plate 24 formed of insulating material into the vacuum processing chamber 26 so as to generate plasma 38.

In addition, a plasma emission distribution measurement system is equipped to the plasma etching apparatus illustrated in the present embodiment. The plasma emission distribution measurement system is composed of a motor 140, a rotation transmitting shaft 142, a light receiving unit 144, a rotation feed-through 146, an optical fiber 148, a spectroscope 150 and a computer 154. We will now describe the plasma emission distribution measurement system. The driving mechanism of the plasma emission distribution measurement system is composed of the motor 140 and the rotation transmitting shaft 142, and a light receiving unit 144 is connected to the rotation transmitting shaft 142. The rotation transmitting shaft 142 and the light receiving unit 144 are rotated by driving the motor 140. Furthermore, by disposing an angle sensor on the rotation shaft of the motor 140, the light receiving direction can be obtained accurately.

As shown in FIG. 1, the rotation transmitting shaft 142 is inserted through the rotation feed-through 146 to the vacuum processing chamber 26, so that the plasma emission distribution measurement system can be installed and driven while maintaining a decompressed pressure in the vacuum processing chamber 26. Further, an optical fiber 148 is connected to the light receiving unit 144 for conducting the emission of plasma 38 received by the light receiving unit 144 to the spectroscope 150. The emission of plasma 38 introduced to the spectroscope 150 has the intensity of each wavelength converted into emission spectral data in the spectroscope 150 and output therefrom. The output emission spectral data 152 is transmitted to the computer 154. The emission spectral data 152 is transmitted to the computer 154 and stored. The computer 154 outputs a drive signal 156 to the motor 140, by which the rotation of the motor 140 is controlled.

Furthermore, upon storing the emission spectral data 152 in the computer 154, the data is associated with the rotary position of the motor 140 so that the emission spectral data 152 is associated with the light receiving direction of the light receiving unit 144, by which the plasma emission distribution in the vacuum processing chamber 26 is obtained. Furthermore, the emission intensity of the desired radical can be obtained by extracting only the light existing in a predetermined wavelength region of the plasma emission spectrum by the computer 154.

The emission intensity distribution thus obtained is an integration value of plasma emission within the line of sight observed from the light receiving unit, so the value must be converted into spatial distribution of emission intensity in the computer. The plasma is in a substantially axisymmetric distribution in the processing apparatus, so it is preferable to utilize Abel inversion for the above-mentioned conversion. If it is not possible to achieve a symmetric property in the processing apparatus, it is preferable to dispose light receiving units at multiple locations and to perform a computer-tomography calculation of the emission data obtained from the multiple light receiving units.

The spatial distribution of radical emission obtained by the conversion is not directly equal to radical density distribution, since it is influenced by the electron density distribution and electron temperature distribution in the plasma. It is possible to perform process control without removing the influence of the electron density and electron temperature distribution, but in order to perform a more accurate process control, it is preferable to suppress the influence of electron density and electron temperature distribution as much as possible. Therefore, an actinometry is performed to normalize the desired radical emission of each spatial position using the emission of inert gas such as Ar, He, Ne, Kr and Xe.

Moreover, the computer 154 sends a control data 158 to a control computer 160 of the plasma etching apparatus based on the achieved density distribution of each radical. Thereafter, the control computer 160 sends control signals 162 to the center-side gas system 70-1 and the circumference-side gas system 70-2, based on which the flow rate control means and valves of the systems are controlled, according to which the compositions and flow rates of the first processing gas 36-1 and the second processing gas 36-2 are controlled.

The above-mentioned arrangement is used to feed a first processing gas 36-1 and a second processing gas 36-2 having different compositions to the vacuum processing chamber 26. For example, when utilizing a mixed gas composed of chlorine (Cl₂), hydrogen bromide (HBr) and oxygen (O₂), the density of oxygen radicals can be set higher at the circumferential portion than at the center portion on the surface of the substrate 1 by reducing the flow rate of oxygen in the first processing gas 36-1 fed through the center-side gas feed area 34-1 than the flow rate of oxygen in the second processing gas 36-2 fed through the circumference-side gas feed area 34-2. Conversely, the density of oxygen radicals can be set lower at the circumference portion than at the center portion on the surface of the substrate 1 by increasing the flow rate of oxygen in the first processing gas 36-1 than the flow rate of oxygen in the second processing gas 36-2.

Similarly, the density distribution of chlorine radicals can be controlled by controlling the flow rates of chlorine in the first processing gas 36-1 and the second processing gas 36-2, and in addition, when a processing gas such as CF₄ (carbon tetrafluoride) is used, the density distribution of fluorocarbon-based radicals can be controlled by controlling the flow rates of the first processing gas 36-1 and the second processing gas 36-2 in a similar manner.

During gate etching, Cl (chlorine), Br (bromine) and O (oxygen) radicals generated by dissociating processing gas react with the polysilicon film, by which silicon-based reaction products are generated. The volatile reaction products are taken away through the exhaust port 40, but a portion of the nonvolatile reaction products stick to and deposit on the polysilicon film and photoresist mask, functioning as a side-wall protection film against etching caused by radicals of etchant such as chlorine. Therefore, if the amount of deposits on the side walls of the gate electrode is small, isotropic etching of the side walls of the gate electrode is performed by the etchant radicals, and as a result, the width of the gate electrode (gate width) after the etching process is often reduced. On the other hand, if the amount of deposits on the side walls of the gate electrode is large, the deposits constitute a mask against etching, and as a result, the gate width after the etching process is often large. Furthermore, the value obtained by subtracting the mask dimension prior to processing from the width of the gate electrode after the etching (also referred to as CD or critical dimension) is called a CD shift, which is an important indicator representing the quality of the etching process, and a target value thereof is set in advance.

Further, it is known that the deposition property of reaction products becomes stronger when silicon-based reaction products are bound with oxygen radicals. Therefore, if the density of oxygen radicals is increased at a certain area, the amount of deposits on the side walls of the gate electrode is increased compared to the area where the density is low, and as a result, the gate width can be increased, that is, the CD shift can be increased. Moreover, when fluorocarbon gas such as CF₄ (carbon tetrafluoride) is used as the processing gas, carbon-based radicals having a strong deposition property are generated and are deposited on the side walls of the gate electrode, so that if the density of carbon-based radicals is increased similarly at a certain area, the CD shift can be increased compared to other areas where the density is low. Furthermore, if the density of chlorine radicals is increased in a certain area, the amount of isotropic etching of the side walls of the gate electrode in that area is increased compared to other areas having a low density, and the CD shift can be reduced. Thus, by controlling the amount of oxygen, fluorocarbon gas or chlorine contained in the first and second processing gases 36-1 and 36-2, it becomes possible to control the in-plane CD shift distribution on the surface of the substrate 1.

Moreover, the above-mentioned plasma emission distribution measurement system can be used to measure the emission intensity of the desired radicals in a desired direction. The data on the emission intensity of each radicals and the light receiving direction of the light receiving unit 144 are processed via Abel inversion so as to compute the radial direction distribution of the radical emission intensity, and thus, the density distribution of respective radicals can be obtained.

Furthermore, it is important that the range of rotation of the light receiving unit 144 is wide enough to obtain the radical density distribution of the area including at least the whole diameter of the substrate 1. Furthermore, since the radical density distribution of the area near the surface of the substrate 1 is closely related, it is desirable that the light receiving height of the light receiving unit 144 is higher than the substrate 1 but as close as possible to the surface of the substrate 1.

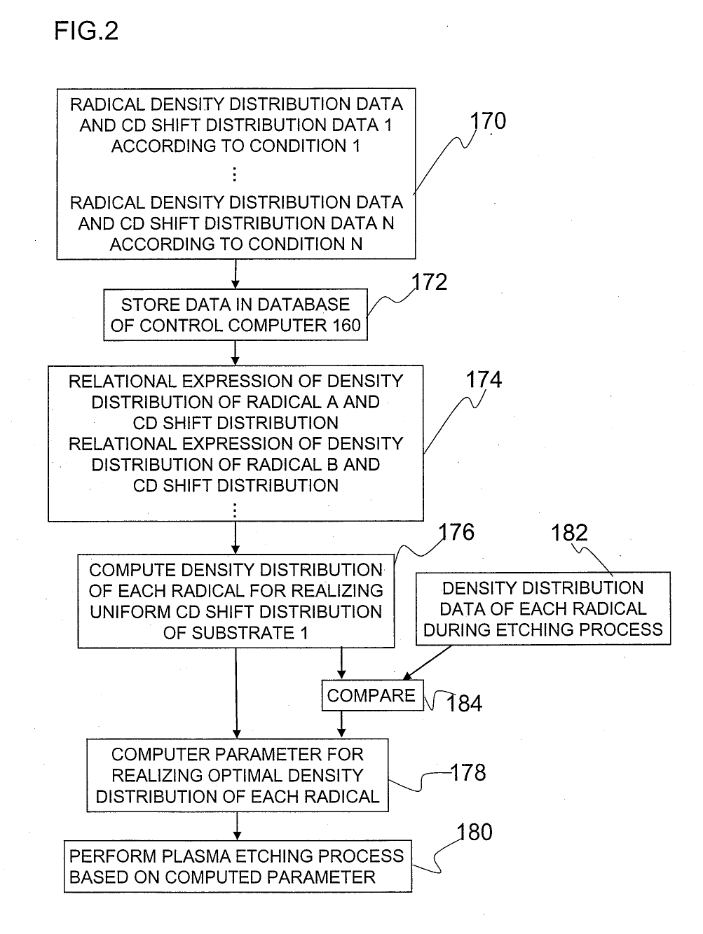

The flowchart shown in FIG. 2 is referred to in describing the actual process for determining the plasma etching conditions of the present embodiment. In FIG. 2, the gate etching process of the substrate 1 is performed in advance for N times with the compositions and flow rates of the first and second processing gases 36-1 and 36-2 varied, and the radical density distribution in the plasma 38 at that time is measured by the aforementioned plasma emission distribution measurement system. Further, the CD shift distribution of each process is measured, and the data is obtained (step 170). For example, the process is performed under a condition in which the first processing gas 36-1 is composed of HBr, Cl₂, O₂ and Ar mixed in the amount of 50 sccm, 50 sccm, 5 sccm and 10 sccm and the second processing gas 36-2 is composed of the same gases mixed in the same amounts (hereinafter called condition A), and the density distribution of the radical species and the CD shift distribution are obtained. This constitutes one of the data obtained by the etching performed in advance for N times (at least two times). It is desirable to measure the density distribution of a plurality of radical species during measurement by the plasma emission distribution measurement system. For example, it is preferable to measure the density distribution of respective radical species such as H, Br, Cl and O generated by the dissociation of the processing gas, radical species such as SiBr, Si, SiCl and SiCl₂ generated by the etching of Poly-Si, and Ar contained in the processing gas. In order to perform the aforementioned actinometry, it is preferable to add Ar or other inert gas to the processing gas for performing processing regardless of whether it is necessary for the etching reaction.

Furthermore, in step 170, in order to clarify the relationship between the compositions and flow rates of the first and second processing gases 36-1 and 36-2 and the CD shift distribution, it is preferable to set the processing conditions other than the compositions and flow rates of the first and second processing gases 36-1 and 36-2, such as the temperature distribution of the substrate 1, the processing pressure and the UHF power applied to the antenna 52, to the same values during the gate etching process performed for N times.

The data on the CD shift distribution achieved as the result of the gate etching process performed for N times in advance, the processing conditions during each of the processes such as the compositions and flow rates of the first and second processing gases 36-1 and 36-2, the temperature distribution of the substrate 1, the processing pressure and the UHF power applied to the antenna 52, and the data on the density distribution of radicals are stored in the database in the control computer 160 (step 172).

Next, the control computer 160 computes the relational expression of the density distribution of the respective radicals and the CD shift distribution (step 174).

Next, the control computer 160 computes the density distribution of the respective radicals for realizing a uniform CD shift distribution within the plane of the substrate 1 based on the relational expression of the density distribution of respective radicals and the CD shift distribution obtained in step 174 (step 176).

Next, the compositions and flow rates of the first and second processing gases 36-1 and 36-2 are computed in order to realize the density distribution of the respective radicals computed in step 176 (step 178).

Next, the etching process is performed utilizing the compositions and flow rates of the first and second processing gases 36-1 and 36-2 computed in step 178 (step 180). At this time, the etching process is performed so that the processing conditions other than the compositions and flow rates of the first and second processing gases 36-1 and 36-2 are the same as those in the etching performed for N times in step 170. Further, since the etching process of step 180 is performed under a condition optimized so that the in-plane CD shift distribution becomes uniform, it is not necessary to measure the radical density distribution during the etching process using the plasma emission distribution measurement system.

However, when the etching apparatus is used for a long period of time, the radical distribution within the vacuum processing chamber 26 may vary with time. In this case, it is effective to measure the plasma emission during the etching process using the plasma emission distribution measurement system and perform a real-time control of the processing conditions while performing the etching process. In this case, at first, the density distribution of the respective radicals is measured using the plasma emission distribution measurement system, and the density distribution data of the respective radicals is sent to the control computer 160 (step 182). Next, the data is compared with the computation results of the density distribution of the respective radicals for realizing a uniform in-plane CD shift distribution of the substrate 1 computed in step 176 (step 184), and as a result, the computer 154 computes the parameters for realizing the most appropriate density distribution of the respective radicals (step 178), which is reflected on the plasma etching conditions for performing the process (step 180). If steps 182, 184, 178 and 180 are performed once in two seconds during the etching process, for example, the radical density distribution can be controlled in real time during etching.

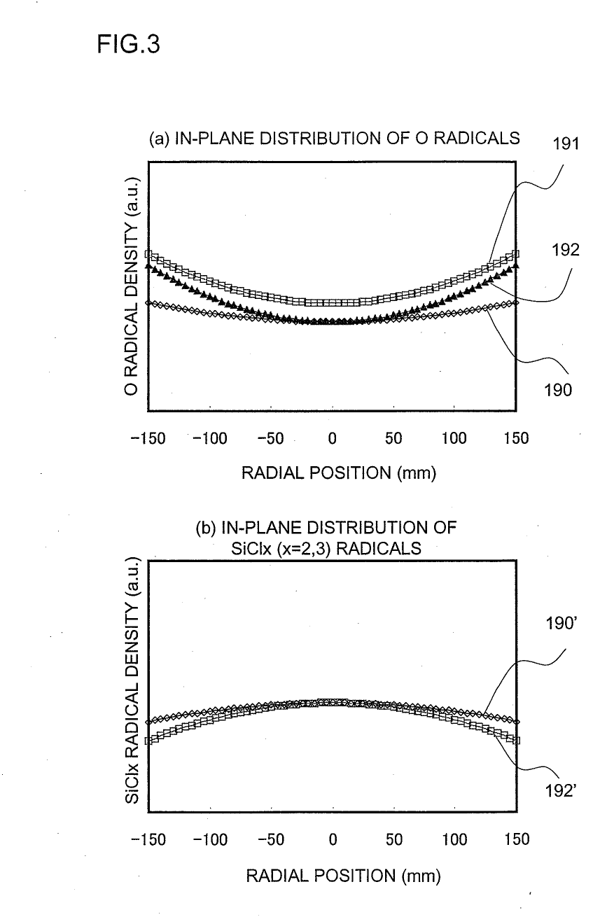

Next, the effects of the present embodiment will be described. FIG. 3(a) shows an in-plane distribution 190 of O radicals on the surface of the substrate 1 when etching is performed under the aforementioned condition A, and an in-plane distribution 192 of O radicals computed in step 176 so as to realize a uniform CD shift. The respective in-plane distributions are composed of data corresponding to 100 positional points on the surface of the substrate 1 having a diameter of 300 mm. According to condition A, as shown by the in-plane distribution 190 of O radicals, the density at the circumference portion is lower than that of the in-plane distribution 192. In order to correct the same, the oxygen flow rate of the second processing gas 36-2 is increased by 3 sccm than condition A, that is, to 8 sccm. Since the circumference-side gas feed area 32-2 through which the second processing gas 36-2 is introduced is disposed toward the outer circumference than the center-side gas feed area 32-1, the density of O radicals at the circumference portion near the surface of the substrate 1 is increased by the influence of the second processing gas 36-2. If the oxygen flow rate of the second processing gas 36-2 is increased in the above manner, the density at the circumference portion becomes higher than at the center portion of the substrate 1, however, the density at the center portion is also increased by the influence of the second processing gas 36-2, according to which a distribution as shown by in-plane distribution 191 occurs. In order to correct the same, the present embodiment reduces the oxygen flow rate of the first processing gas 36-1 by 2 sccm than condition A, that is, to 3 sccm, so as to realize an in-plane distribution 192 in which the O radical density is equal to condition A at the center portion and higher at the outer circumference portion.

Furthermore, with respect to FIG. 3(a), the reason why the in-plane CD shift is more uniform according to the O-radical in-plane distribution 192 having a higher density at the outer circumference portion than according to the O-radical in-plane distribution 190 having a flatter distribution is because, as mentioned above, the tendency of the CD shift being smaller at the outer circumference portion than at the center portion of the substrate 1 is cancelled and corrected by the O radical density being increased at the outer circumference portion to thereby enhance the deposition property of reaction products and increase the CD shift.

Moreover, FIG. 3(b) shows an in-plane distribution of SiClₓ (x=2, 3) radicals on the surface of the substrate 1. The distribution obtained by performing etching under condition A is shown in in-plane distribution 190′, and the distribution realized by applying the present invention to control the oxygen flow rate is shown in in-plane distribution 192′. In the in-plane distribution 192′, the density of SiClx radicals at the outer circumference portion of the substrate 1 is slightly reduced compared to condition A. This is considered to be caused by the application of the present invention increasing the O radical density at the outer circumference portion, which lead to the increase of the amount of deposition of reaction products forming a protection film against etching.

As described, by comprehending not only the in-plane distribution of O radicals shown in FIG. 3(a) but also the in-plane distribution of SiClx radicals, it becomes possible to comprehend the status of the plasma 38 in detail. Thus, the control accuracy of the in-plane distribution of the CD shift of the substrate 1 is improved.

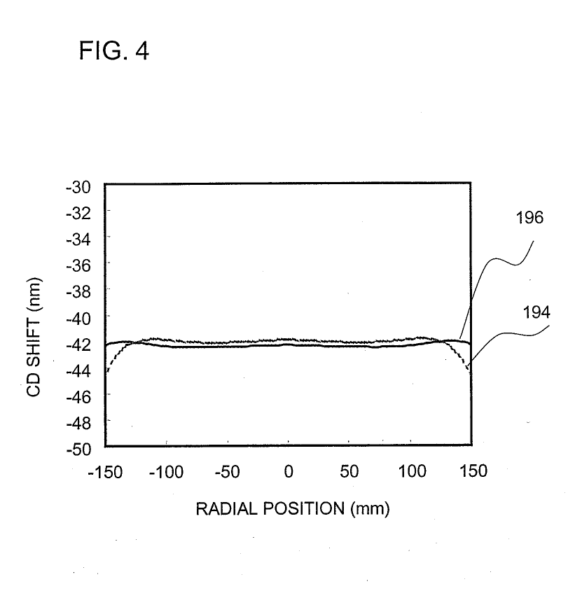

Next, FIG. 4 shows a CD shift distribution 194 according to condition A and a CD shift distribution 196 in which the present invention is applied to perform control. According to the CD shift distribution 196, the CD shift in the radial position of 100 mm and smaller became greater compared to the CD shift 194 of condition A, and thus, a uniform in-plane distribution was achieved.

Moreover, according to the present embodiment, the density distributions of O radicals and SiClₓ radicals are computed in order to control the flow rate of oxygen in the first and second processing gases 36-1 and 36-2, but the present invention is not restricted thereto, and it is also possible to compute the density distributions of other radicals and to control the corresponding flow rates or compositions of the processing gases. For example, it is possible to compute the density distribution of Cl radicals which are etchant radicals in order to control the flow rates of chlorine in the first and second processing gases 36-1 and 36-2.

According further to the present embodiment, processing gases are fed through two gas feed areas, the center-side gas feed area 34-1 and the circumference-side gas feed area 34-2, but the number of gas feed areas is not restricted to two, and it is possible to provide three or more gas feed areas.

### Embodiment 2

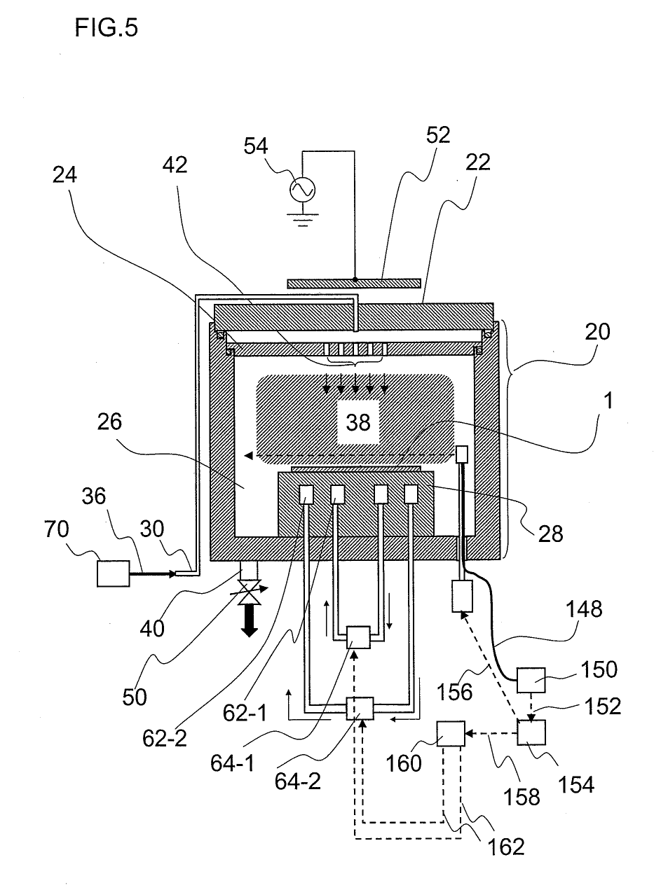

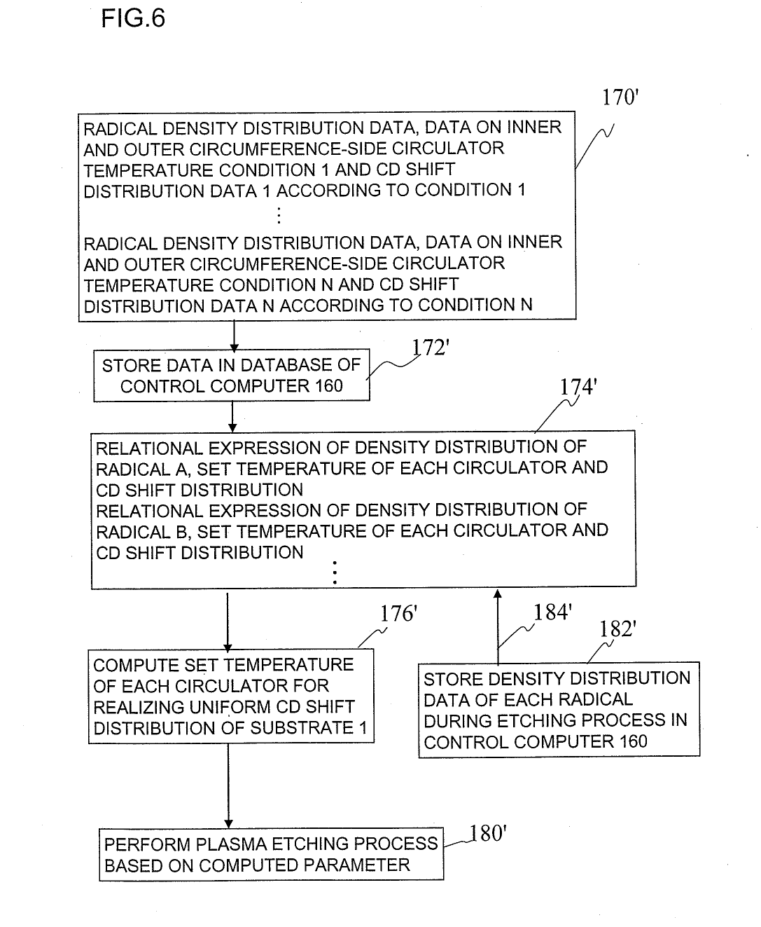

Next, the second embodiment of the present invention will be described with reference to FIGS. 5 and 6. In the present embodiment, the temperature distribution of the substrate 1 is controlled based on the radical density distribution obtained by the plasma emission distribution measurement system, so as to control and uniformize the in-plane distribution of CD shift of the substrate 1. The following describes the differences of the present embodiment from the first embodiment.

In the plasma etching apparatus of FIG. 5, the processing gas is fed through a single gas feed area 42. Multiple lines of temperature control means are provided at various radial positions within the substrate stage 28, and the radial-direction temperature distribution of the substrate 1 is controlled by controlling the temperatures of the temperature control means. According to the present embodiment, an inner circumference-side fluid passage 62-1 and an outer circumference-side fluid passage 62-2 are provided as temperature control means, which are respectively connected to an inner circumference-side circulator 64-1 and an outer circumference-side circulator 64-2, and the set temperature of the fluids circulated through the inner circumference-side fluid passage 62-1 and the outer circumference-side fluid passage 62-2 are controlled so as to control the radial-direction temperature distribution of the substrate 1 to be processed.

In the present embodiment, a control signal 162 is output from the control computer 160 to the inner and outer circumference-side circulators 64-1 and 64-2 so as to control the set temperatures respectively. Furthermore, the relationship between the set temperatures of the inner and outer circumference-side circulators 64-1 and 64-2 and the in-plane temperature distribution in the radial direction of the substrate 1 is computed in advance by tests or numerical simulations.

As described, the deposition of reaction products on the side walls of the gate electrode influence the CD shift, and in general, the reaction products tend to deposit more easily when the temperature becomes lower. Therefore, the CD shift distribution can be controlled by controlling the temperature distribution of the substrate 1. The actual process for determining the plasma etching conditions according to the present embodiment will be described with reference to the flowchart of FIG. 6. In FIG. 6, similar to the first embodiment, gate etching of the substrate 1 is performed in advance for N times with the compositions and flow rates of the processing gases varied, and the radical density distributions in the plasma 38 and the CD shift distributions according to the respective processes are measured to obtain data (step 170′). For example, the data on the radical density distribution in the plasma 38 and the CD shift distribution is obtained by using a processing gas composed of 50 sccm of HBr, 50 sccm of Cl₂, 5 sccm of O₂ and 10 sccm of Ar, and the set temperatures of the inner and outer circumference-side circulators 64-1 and 64-2 respectively set to 40° C. and 25° C. (hereinafter referred to as condition B), and the data constitutes one of the data of the etching process performed in advance for N times. At this time, in order to clarify the relationship between the density distributions of the respective radicals and the CD shift distribution, if the composition or the flow rate of the processing gas is varied, it is preferable that the other processing conditions are the same during the etching process performed for N times.

The data on the CD shift distribution obtained as a result of the gate etching process performed in advance for N times, the processing conditions of each process and the density distribution of radicals are stored in the database of the control computer 160 (step 172′).

Next, the control computer 160 computes the relational expression of the density distribution of the respective radicals, the set temperatures of the inner and outer circumference-side circulators 64-1 and 64-2 and the CD shift distribution (step 174′). For example, if the density of O radicals is reduced at the outer circumference portion of the substrate 1 compared to the O radical distribution of the CD shift distribution that realizes a uniform in-plane distribution of the substrate 1, the CD shift at the outer circumference portion tends to be smaller than at the center portion. In order to prevent this drawback, the set temperature of the outer circumference-side circulator 64-2 is lowered so as to allow the reaction products to be attached more easily to the side walls of the gate electrode, by which the CD shift at the outer circumference portion is increased and the CD shift distribution is controlled to be more uniform.

Furthermore, in order to control the CD shift distribution, it is necessary to obtain in advance a relational expression representing the influence of the density distribution of a certain radical on the CD shift distribution and the influence of the set temperatures of the inner and outer circumference-side circulators 64-1 and 64-2 on the CD shift distribution, and to quantify the same. Based on the processing condition of step 170′, the density distributions of respective radicals measured by the plasma emission distribution measurement system and the CD shift measurement results, and from the data stored in the database of the control computer 160 in step 172′, step 174′ computes the relational expression of the density distributions of the respective radicals and the set temperatures of the inner and outer circumference-side circulators 64-1 and 64-2, the in-plane temperature distribution in the radial direction of the substrate 1 computed based on the set temperature of the circulators, and the CD shift distribution.

Next, the control computer 160 computes, based on the relational expression of the density distributions of the respective radicals, the set temperatures of the respective circulators and the CD shift distribution obtained in step 174′, the set temperatures of the respective circulators for realizing a uniform CD shift distribution within the plane of the substrate 1 (step 176′). For example, according to the present embodiment, if it is determined in step 174′ that the density distribution of O radicals is lower by 20% at the outer circumference portion of the substrate 1 compared to the case in which the in-plane CD shift is uniform, which results in the CD shift at the outer circumference portion being narrowed by 3 nm than the center portion, it is necessary to widen the CD shift by 3 nm at the outer circumference portion so as to realize a uniform CD shift distribution. The set temperatures of the inner and outer circumference-side circulators 64-1 and 64-2 for realizing the same are analyzed. For example, the present embodiment computes that the set temperature of the outer circumference-side circulator 64-2 should be reduced by 5° C. from the 25° C. of condition B to 20° C., and since when the set temperature of the outer circumference-side circulator 64-2 is reduced by 5° C., the temperature of the inner circumference-side of the substrate 1 on the chucked surface is also lowered due to the thermal conductance of the substrate stage, the set temperature of the inner circumference-side circulator 64-1 should be raised by 2° C. from the 40° C. of condition B to 42° C., so as to realize a uniform in-plane distribution of the CD shift.

Next, plasma etching is performed using the set temperatures of the inner and outer circumference-side circulators 64-1 and 64-2 for realizing a uniform CD shift distribution computed in step 176′ (step 180′). Further, the etching in step 180′ is performed under a condition optimized so as to realize a uniform in-plane CD shift distribution, so it is not necessary to measure the radical density distribution using the plasma emission distribution measurement system during the process.

However, when the etching device is used for a long period of time, the radical distribution within the vacuum processing chamber 26 may vary with time. In this case, it is effective to measure the plasma emission during etching using the plasma emission distribution measurement system and to perform a real-time control of the processing conditions. In such case, at first, the density distribution of the respective radicals during etching is measured by the plasma emission distribution measurement system, and the density distribution data of the respective radicals thus obtained is stored in the control computer 160 (step 182′). Next, the density distribution data of the respective radicals is substituted in the relational expression of the density distribution of the respective radicals, the set temperatures of the respective circulators and the CD shift distribution obtained in step 174′ (step 184′). Then, the set temperatures of the respective circulators for realizing a uniform CD shift distribution in the plane of the substrate 1 are computed (step 176′), and the result is reflected on the etching conditions. If steps 182′, 184′ and 176′ are performed once in two seconds during the etching process, for example, it becomes possible to control the temperature distribution of the substrate 1 in real time during etching, and a uniform CD shift distribution can be realized.

By applying the present embodiment described above, it becomes possible to utilize the plasma emission distribution measurement system to measure the radical density distribution in the plasma, to predict the CD shift distribution, to control the temperature of the substrate based on the predicted value, and to uniformize the CD shift distribution.

The set temperatures of two lines of circulators are controlled to adjust the temperature distribution of the substrate 1 according to the present embodiment, but the number of lines of temperature control is not restricted to two lines, and a greater number of lines can be used. If a greater number of lines is used, it becomes possible to control the temperature distribution in further detail in the radial direction of the substrate 1. According further to the present embodiment, circulators are used as a means for controlling the temperature distribution of the substrate 1, but the present invention is not restricted thereto, and it is also possible to control the temperature distribution of the substrate 1 by providing two lines of heaters, an inner circumference-side heater and an outer circumference-side heater, in the substrate stage 28, and to control the heating performed thereby. Using heaters are more advantageous than using circulators since it has better response property of temperature control of the substrate 1. Of course, even when using heaters as the temperature control means, the temperature distribution can be controlled in further detail in the radial direction of the substrate 1 if a greater number of lines is provided.

### Embodiment 3

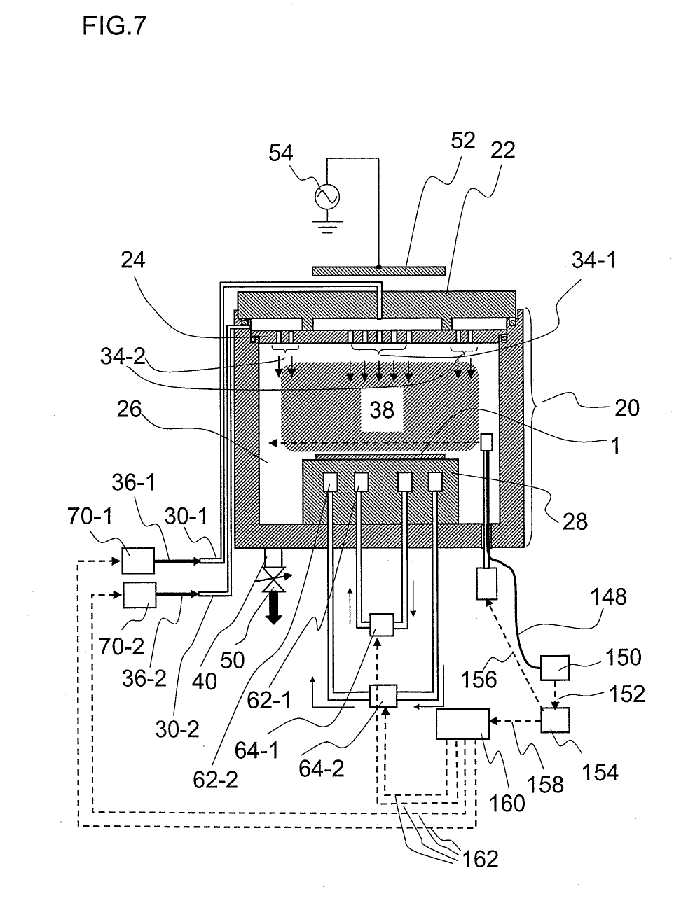

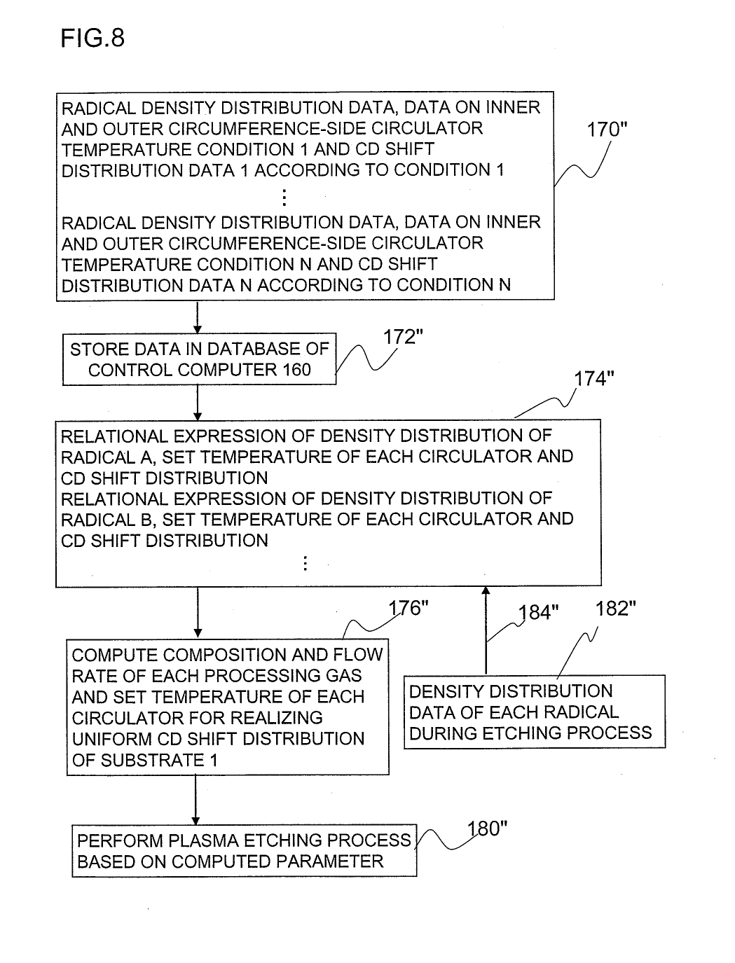

Next, the third embodiment of the present invention will be described with reference to FIGS. 7 and 8. The present embodiment controls the in-plane distribution of CD shift using both the means for controlling the flow rates and compositions of processing gases fed through two or more different gas feed areas and the multiple lines of temperature control means disposed within the substrate stage 28, based on the radical density distribution obtained using the plasma emission distribution measurement system. The following describes the differences between the present embodiment and the aforementioned first and second embodiments.

In the plasma etching apparatus of FIG. 7, the in-plane distribution of the CD shift of substrate 1 is controlled by adjusting the compositions or flow rates of the first and second processing gases 36-1 and 36-2 and the temperatures of the fluid circulated through the inner and outer circumference-side fluid passages 62-1 and 62-2 formed on the substrate stage 28.

The actual process for determining the gate etching conditions according to the present embodiment will be described with reference to the flowchart of FIG. 8. In FIG. 8, similar to the description of the first embodiment, gate etching of the substrate 1 is performed in advance for N times with the compositions and flow rates of the first and second processing gases 36-1 and 36-2 varied, and the density distributions of radicals in the plasma 38 are measured using the plasma emission distribution measurement system, and further, the CD shift distributions of the respective processes are measured to obtain data (step 170″). For example, the data on the density distributions of radical species and the CD shift distribution is obtained under a condition using a first processing gas 36-1 composed of 50 sccm of HBr, 50 sccm of Cl₂, 5 sccm of O₂ and 10 sccm of Ar, a second processing gas 36-2 composed of 50 sccm of HBr, 50 sccm of Cl₂, 5 sccm of O₂ and 10 sccm of Ar, and setting the respective temperatures of the inner and outer circumference-side circulators 64-1 and 64-2 to 40° C. and 25° C. (hereinafter referred to as condition C), the data constituting one of the data of the etching performed in advance for N times. At this time, in order to clarify the compositions and flow rates of the first and second processing gases 36-1 and 36-2, the set temperatures of the inner and outer circumference-side circulators 64-1 and 64-2 and the CD shift distribution, if the compositions or flow rates of the first and second processing gases 36-1 and 36-2 are varied, it is preferable that the other processing conditions are maintained the same during the etching process performed for N times.

The data on the CD shift distribution obtained as a result of the gate etching process performed in advance for N times, the processing conditions of each process and the density distribution of radicals are stored in the database of the control computer 160 (step 172″).

Next, the control computer 160 computes the relational expression of the density distributions of the respective radicals, the set temperatures of the inner and outer circumference-side circulators 64-1 and 64-2 and the CD shift distribution (step 174″). For example, if the density of O radicals is reduced at the outer circumference portion of the substrate 1 compared to the O radical distribution when the in-plane CD shift distribution of the substrate 1 is uniform, the CD shift at the outer circumference portion tends to be smaller than the center portion. In order to prevent this drawback, the set temperature of the outer circumference-side circulator 64-2 is reduced so as to allow the reaction products to be stuck more easily to the side walls of the gate electrode, and the flow rate of oxygen in the second processing gas 36-2 is increased, by which the CD shift at the outer circumference portion is controlled to be increased. Furthermore, in order to control the CD shift distribution, it is necessary to obtain in advance a relational expression representing the influence of the density distribution of a certain radical on the CD shift distribution and the influence of the set temperatures of the inner and outer circumference-side circulators 64-1 and 64-2 on the CD shift distribution, and to quantify the same. Based on the processing condition of step 170″, the density distribution of respective radicals measured by the plasma emission distribution measurement system and the CD shift measurement results, and by the data stored in the database of the control computer 160 in step 172″, step 174″ computes the relational expression of the compositions and flow rates of the first and second processing gases 36-1 and 36-2, the density distribution of the respective radicals, the set temperatures of the inner and outer circumference-side circulators 64-1 and 64-2, the in-plane temperature distribution in the radial direction of the substrate 1 computed based on the set temperatures of the circulators, and the CD shift distribution.

Next, the control computer 160 computes, based on the relational expression of the density distributions of the respective radicals, the set temperatures of the respective circulators and the CD shift distribution obtained in step 174″, the flow rates and compositions of the respective processing gases and the set temperatures of the respective circulators for realizing a uniform CD shift distribution within the plane of the substrate 1 (step 176″). For example, according to the present embodiment, if it is determined in step 174″ that compared to the case in which the in-plane CD shift is uniform, the density distribution of O radicals is lower by 20% at the outer circumference portion of the substrate 1, which results in the CD shift at the outer circumference portion being narrowed by 3 nm than at the center portion, it is necessary to widen the CD shift by 3 nm at the outer circumference portion so as to realize a uniform CD shift distribution. The set temperatures of the inner and outer circumference-side circulators 64-1 and 64-2 and the compositions and flow rates of the first and second processing gases 36-1 and 36-2 for realizing the same are analyzed. For example, the present embodiment computes that a uniform in-plane CD shift distribution can be realized by reducing the oxygen flow rate of the first processing gas 36-1 by 1 sccm to 4 sccm and increasing the oxygen flow rate of the second processing gas 36-2 by 1.5 sccm to 6.5 sccm, increasing the set temperature of the inner circumference-side circulator 64-1 by 1° C. to 41° C. and reducing the set temperature of the outer circumference-side circulator 64-2 by 2.5° C. to 22.5° C. compared to condition C.

Next, a plasma etching process is performed using the compositions and flow rates of the first and second processing gases 36-1 and 36-2 and the set temperatures of the inner and outer circumference-side circulators 64-1 and 64-2 computed in step 176″ (step 180″). Further, the etching in step 180″ is performed under a condition optimized so as to realize a uniform in-plane CD shift distribution, so it is not necessary to measure the radical density distribution using the plasma emission distribution measurement system during the process.

However, when the etching apparatus is used for a long period of time, the radical distribution within the vacuum processing chamber 26 may vary with time. In this case, it is effective to measure the plasma emission during etching using the plasma emission distribution measurement system and to perform a real-time control of the processing conditions. In such case, at first, the density distribution of the respective radicals during etching is measured using the plasma emission distribution measurement system, and the density distribution data of the respective radicals thus obtained is stored in the control computer 160 (step 182″). Next, the density distribution data of the respective radicals is substituted in the relational expression of the density distribution of the respective radicals, the set temperatures of the respective circulators and the CD shift distribution obtained in step 174″ (step 184″). Then, the compositions and flow rates of the first and second processing gases 36-1 and 36-2 and the set temperatures of the respective circulators for realizing a uniform CD shift distribution of the substrate 1 obtained in step 176″ is computed, and the result is reflected on the conditions for the etching process (step 180″). If steps 182″, 184″ and 180″ are performed once in two seconds during the etching process, for example, real-time control of processing conditions during etching is performed, and a uniform CD shift distribution can be realized.

According to the above embodiment, it becomes possible to use the plasma emission distribution measurement system to measure the radical density distribution in the plasma, to predict the CD shift distribution, to control the flow rates and compositions of the processing gases and the temperature distribution of the substrate 1 based on the predicted value, and to uniformize the CD shift distribution. As described in the present embodiment, by utilizing both the control means of the first and second embodiments, the amount of control of CD shift can be increased compared to the case in which each control means is used by itself, and it becomes possible to correspond to a wide range of etching conditions. Moreover, the CD shift distribution can be controlled with better response property compared to the case in which each control means is used by itself.

### Embodiment 4

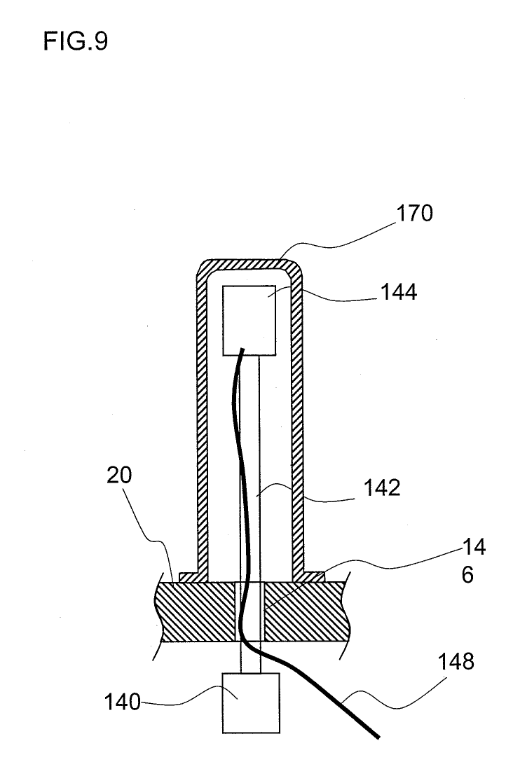

Next, the fourth embodiment of the present invention will be described with reference to FIG. 9. In the first through third embodiments, the light receiving unit 144 and the rotation transmitting shaft 142 of the plasma emission distribution measurement system were directly exposed to plasma 38. It is possible to use materials such as polyimide to form these members so that they have resistance to corrosion from the plasma 38, but if they are to be used for a long period of time, it is necessary that they are protected by a cover or the like. In FIG. 9, a cover 170 made of quartz is arranged to cover the light receiving unit 144 and the rotation transmitting shaft 142 of the plasma emission distribution measurement system illustrated in embodiments 1 through 3. Furthermore, by designing the light receiving unit 144 and the rotation transmitting shaft 142 to be rotated within the cover, it becomes possible to change the direction of the light receiving unit 144 while receiving the light emitted from the plasma 38, so that the density distribution of various radicals in the plasma 38 can be measured. According to the present embodiment, it becomes possible to measure the radical density distribution in the plasma 38 for a long period of time.

### Embodiment 5

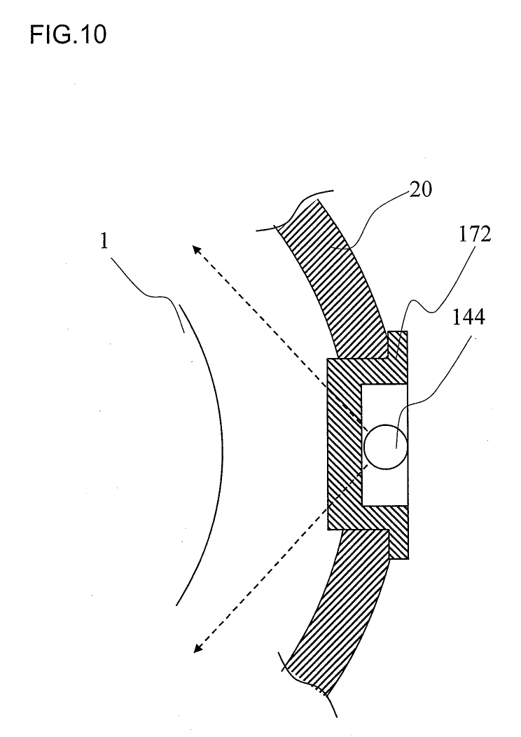

Next, the fifth embodiment of the present invention will be described with reference to FIG. 10. Similar to the fourth embodiment, the present embodiment considers long-term use of the plasma emission distribution measurement system, wherein a quartz window 172 is embedded in the wall 20 of the processing chamber, and the light receiving unit 144 of the plasma emission distribution measurement system is provided on the outer side (on the atmospheric side) of the window 172. By enabling the light receiving unit 144 to be rotated, it becomes possible to change the direction of the light receiving unit 144 while receiving the light emitted from the plasma 38, so that the density distribution of various radicals in the plasma 38 can be measured. According to the present embodiment, it becomes possible to measure the radical density distribution of the plasma 38 for a long period of time.

### Embodiment 6

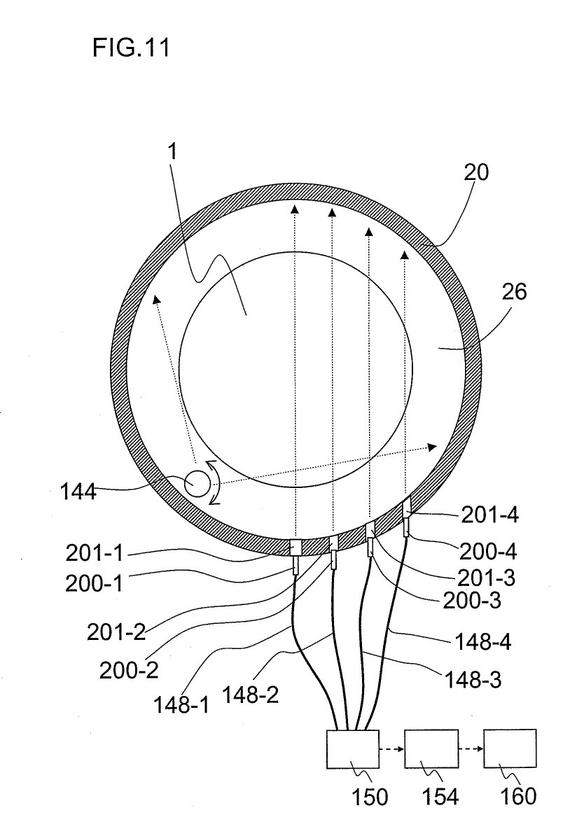

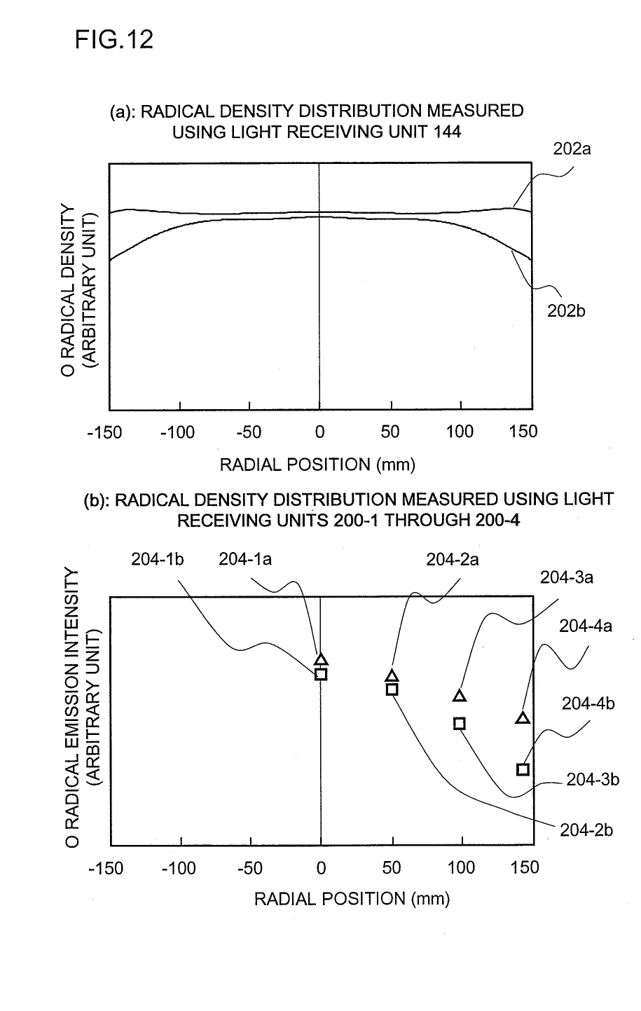

Next, the sixth embodiment of the present invention will be described with reference to FIGS. 11 and 12. The present embodiment disposes a plurality of light receiving units in the direction of observation suitable for extracting the radical density distribution in the processing chamber, and computes in real time during the etching process the radical and plasma distribution in the chamber based on the plurality of observation data obtained by the plurality of light receiving units as compared with the database prepared in advance. The present embodiment considers long-term use of the plasma emission distribution measurement system, and in addition, simplifies the structure of the distribution measurement means. As shown in FIG. 11, in order to observe the area on the surface of the substrate 1 ranging from the center to the outer circumference thereof in the direction parallel to the surface of the substrate 1, a plurality of (four in the present drawing) windows 201-1 through 201-4 are arranged at even intervals on the wall of the processing chamber, and light receiving units 200-1 through 200-4 are arranged to face the windows, by which the plasma generated in the vacuum processing chamber 26 is observed. According to this arrangement, the light receiving units 200-1 through 200-4 must be arranged at observation directions suitable for extracting the radical density distribution in the plasma. In the present embodiment, the light receiving units are arranged so that a length of the path through which each light receiving unit observes the plasma in the transverse direction (hereinafter referred to as optical path) differs for each light receiving unit, and at the same time, is parallel with the optical paths of other units. Furthermore, the plasma emission received by the light receiving units is the integration value of plasma emission existing in the optical path passing transversely across the processing chamber 26, as illustrated by the dotted arrowed lines of FIG. 11. Furthermore, when receiving light using the light receiving units 200-1 through 200-4, it is important that the light receiving unit 144 of the plasma emission distribution measurement system is arranged so as not to interfere with the optical paths. The actual method of use of the present system will be described in detail below.

At first, upon performing etching for N times in advance and acquiring data on the correlation of the radical density distribution and the CD shift distribution using the plasma emission distribution measurement system as illustrated in the first to third embodiments, the light emitted from the plasma (not shown) is received by the plurality of light receiving units 200-1 through 200-4 illustrated in FIG. 11. Each light receiving unit 200-1 through 200-4 has an optical fiber 148-1 through 148-4 connected respectively thereto, and the received plasma emission is transmitted to a spectroscope 150. The intensities of respective wavelengths of the plasma emission transmitted to the spectroscope 150 are converted into emission spectral data at the spectroscope 150, and sent to the computer 154. The computer 154 identifies the radical species and computes the emission peak intensity of each radical species. Further, the radial position thereof is computed based on the set positions of the light receiving units 200-1 through 200-4, the result of which is combined with the emission peak intensity of each radical. In this case, a path perpendicularly crossing the optical paths of the light receiving units and passing the center of the processing chamber 26 is set as an axis, and the coordinates on the axis show the radial positions. At this time, by rotating the light receiving unit 144 of the plasma emission distribution measurement system, and based on the method shown in the first to third embodiments, it becomes possible to achieve the radical density distribution. Further, the CD shift by the etching process is measured. According to the above process, similar to the first to third embodiments, during the plurality (N times) of processes performed in advance before the actual etching process, the peak intensity of each radical at multiple radial positions, the density distribution of each radical and the CD shift distribution are acquired, the data of which are correlated and stored in the database of the control computer 160.

After acquiring these data, even if the light receiving unit 144 of the plasma emission distribution measurement system is removed, the actual radical density distribution 190 during etching can be computed in real time by using only the light receiving units 200-1 through 200-4. At this time, an example of the O radical density distribution measured by the light receiving unit 144 during the plurality (N times) of processes performed in advance is shown in FIG. 12(a), and an example of the emission peak intensity distribution of O radicals measured using the light receiving units 200-1 through 200-4 is shown in FIG. 12(b). The O radical density distribution 202a shows a substantially uniform distribution throughout the plane. The emission peak intensity distribution of O radicals measured using the light receiving units 200-1 through 200-4 during the process is shown in 204-1a through 204-4a. The reason why the O radical density distribution 202a is substantially uniform whereas according to the emission peak intensity distribution 204-1a through 204-4a the intensity is reduced toward the outer radial position is that the integration value of O radical emission reduces as the position becomes close to the outer side and the optical path length becomes shorter. Further, the O radical density distribution in the process performed according to a different processing condition is 202b, and the emission peak intensity distribution of O radicals measured during the process using the light receiving units 200-1 through 200-4 is shown in 204-1b through 204-4b. As described, since the radical density distribution and the radical peak intensity at multiple radial positions are mutually correlated and stored in the database, even if the light receiving unit 144 of the plasma emission distribution measurement system disposed in the processing chamber 26 is removed after the N times of etching processes performed in advance, it becomes possible to use the radical emission peak intensity obtained by the light receiving units 200-1 through 200-4 to refer to the database and acquire a detailed radical density distribution. In addition, since according to the present system there is no need to dispose the light receiving unit 144 in the processing chamber 26 after completing the etching performed in advance for N times, the stability of long-term operation of the etching process is enhanced. Furthermore, since it is possible to achieve the detailed radical density distribution without mechanically rotating the light receiving unit 144, and since it is not necessary to perform computing processes such as the Abel inversion which is mathematically advanced, it becomes possible to achieve the radical density distribution at high speed. This is advantageous in performing control of the processing conditions based on the measurement results of the radical density distribution.

For example, in the etching process performed after the etching process performed in advance for N times, the emission peak intensity distribution of O radicals measured using the plurality of light receiving units 200-1 through 200-4 shows a distribution as shown in 204-1b through 204-4b by influences such as the time variation of the etching apparatus, it is possible to refer to the database in the control computer to discover that the O radical density distribution will be similar to 202b of FIG. 12(a). If according to the etching process performed in advance for N times, the in-plane distribution of CD shift becomes uniform when the O radical density distribution is as shown in 202a, the CD shift will become smaller at the outer circumference portion of the substrate 1 according to a processing condition in which the emission peak intensity distribution of O radicals is as shown in 204-1b through 204-4b. In order to prevent this problem, the oxygen flow rate of the processing gas supplied through the outer circumference-side gas feed region 34-2 can be increased (by 2 sccm, for example) as shown in embodiment 1, so as to control the radical emission peak intensity distribution to become equal to 204-1a through 204-4a. According to such control, by referring to a database, it can be seen that the O radical density distribution will be similar to the O radical density distribution 202a, and that the CD shift will be uniform throughout the plane. As described, based on the radical emission peak intensity obtained through light receiving units 200-1 through 200-4, it becomes possible to control the processing conditions so as to improve the in-plane uniformity of CD shift.

The timing for performing such control of the processing conditions can be selected freely by the user of the present invention. For example, in the current semiconductor fabrication, the processing of the substrates is performed in units called lots (for example, one lot includes 25 substrates), so that the radical emission peak intensity obtained through light receiving units 200-1 through 200-4 in the etching process of a certain lot can be used to control the processing conditions of the subsequent lot so as to improve the in-plane uniformity of CD shift. Furthermore, the radical emission peak intensity obtained through light receiving units 200-1 through 200-4 during the processing of a certain substrate can be used to control the processing conditions for the subsequent substrate so as to improve the in-plane uniformity of CD shift. Moreover, if the etching process is composed of multiple steps, it is possible to measure the radical emission peak intensity using light receiving units 200-1 through 200-4 in a certain step, refer to the database, and if it is detected that the in-plane uniformity of CD shift is likely to be deteriorated, control the processing conditions in the subsequent step so as to realize a uniform CD shift by the process. Further, in case the processing conditions are to be controlled per each step, it is necessary to adjust the processing conditions for each step during the N times of etching performed in advance, and to store the radical density distribution, the radical emission peak intensity measured by the plural light receiving units and the CD shift distribution after the etching process in the database. Further, it is also possible to immediately control the processing conditions based on the radical emission peak intensity during etching to perform a real-time control of processing conditions, so as to improve the in-plane uniformity of CD shift.

As described, if the processing conditions for the subsequent step is to be controlled or if real-time control of processing conditions is to be performed based on the radical emission peak intensity acquired in a certain step, if the control object is the temperature distribution of the substrate 1, it is preferable that the response of control is quick, that is, the control for realizing a target temperature is quick. In this case, it is possible to provide two lines of heaters, an inner circumference-side heater and an outer-circumference side heater, in the substrate stage 28, and to control the respective heating thereof so as to control with high response the temperature distribution of the substrate 1.

If the present embodiment is not applied and the plasma emission is measured using only the light receiving units arranged at four locations without acquiring in advance the detailed radical density distribution, only the radical emission peak intensities 204-1a through 204-4a at four points are acquired, and the density distribution at locations between the measurement points cannot be acquired. For example, the density distribution of radicals at locations between measurement points can be estimated through techniques such as polynomial approximation or spline interpolation, but it cannot be guaranteed that the estimated distribution corresponds with the actual radical density distribution. As mentioned, the in-plane CD shift dispersion in the order of nanometers creates a problem in the current semiconductor mass production, so it is not sufficient to only obtain the radical density distribution of a few locations, and it is important to obtain a highly accurate radical density distribution throughout the area covering the radius of the substrate 1.

Furthermore, it is important that a plurality of light receiving units are arranged in the observation direction suitable for extracting the radical density distribution in the processing chamber, and according to the present embodiment, four light receiving units 200-1 through 200-4 are arranged at even intervals on the processing chamber wall so as to measure the region from the center to the outer circumference on the surface of the substrate 1. However, the locations of the light receiving units are not restricted thereto. For example, it is possible to arrange the plurality of light receiving units on the upper portion of the processing chamber 26 so that they are at different radial positions facing the substrate 1. However, if the distance in the height of the plasma 38, that is, the distance between the center-side gas feed area 34-1 and the substrate 1 is long, the influence from the radical emission in the area other than near the surface of the substrate 1 becomes strong. Since the radicals near the surface of the substrate 1 strongly influence the etching process, the SN ratio may be deteriorated in the above case. Further according to the present embodiment, the light receiving units are arranged so that the optical path lengths of plasma differ for each light receiving unit. This is because the radical density distribution in the plasma is axisymmetric since the processing chamber 38 has a substantially cylindrical shape. If the light receiving units are arranged so that the optical path length of plasma received by the light receiving units are all equal, the radical emission peak intensity obtained through the light receiving units become equal and the in-plane distribution cannot be obtained. Therefore, it is preferable to arrange the light receiving units so that the optical path lengths of plasma differ for each light receiving unit, as described in the present embodiment. Moreover, the light receiving units in the present embodiment are arranged so that the optical path of plasma received by each unit is parallel with the other paths, but if the optical path length of plasma of the units are varied, effects similar to those of the present embodiment can be achieved even if the optical paths are not parallel. Further, there are four light receiving units disposed on the processing chamber wall according to the present embodiment, but the number is not restricted thereto. The spatial resolution performance of the plasma emission distribution in the processing chamber 26 is improved as the number is increased, but if the number is too large, there are drawbacks such as the necessity of a large installation space and the complexity of structure. According to the studies performed by the present inventors, it has been discovered that the appropriate number of light receiving units ranges from 3 to 10, and in the present embodiment, the number is four.

According to the present embodiment, there are four light receiving units 200-1 through 200-4 arranged at even intervals from the center of the substrate 1 toward the outer circumference thereof, but the present invention is not restricted to this example, and the interval can be uneven. For example, in an etching apparatus utilizing ICP (inductively-coupled plasma), the plasma density tends to be higher near the inductive coupling coil. In correspondence thereto, the light receiving unit should be disposed at the peak radial position near the inductive coupling coil where the density becomes highest to measure the radical emission peak intensity, which is combined with the emission peak intensity data from other light receiving units and referred to the database to obtain a detailed radical density distribution.

According further to the present embodiment, light receiving units 200-1 through 200-4 are disposed so as to receive emission through windows formed on the processing chamber wall, but during long-term operation, deposits may adhere on the inner side (vacuum side) of the window, or the window may be etched by the plasma and tarnished, by which the received intensity may be weakened. In that case, the influence can be reduced by setting the emission peak intensity of a certain radical (such as argon) as reference, and utilizing a ratio thereof with the emission peak intensity of the target radical (such as O). The radical used as reference for the emission peak should preferably be an inert gas that is less subject to influence from radical density distribution since it does not react with other radicals.

Further according to the present embodiment, the method for controlling the processing conditions controlled the flow rates and compositions of the processing gases supplied through two or more gas feed areas similar to the first embodiment, but it is not restricted thereto, and it is possible to control the temperatures of the plural lines of temperature control means formed in the substrate stage 28 similar to the second embodiment, or to control both the means for controlling the flow rates and compositions of the processing gases fed from two or more gas feed areas and the plural lines of temperature control means formed in the substrate stage 28 similar to the third embodiment.

Based on the density distribution of the respective radicals obtained as above, and by applying the method and control illustrated in embodiments 1 through 3, the density distribution of various radicals during etching can be obtained at high speed using the light receiving units 200-1 through 200-4 disposed at multiple locations, and plasma etching can be performed by performing control so as to realize a uniform in-plane distribution of the CD shift. By applying these methods, plasma etching can be performed with superior long-term operability to realize a uniform in-plane CD shift distribution advantageously in the mass production of semiconductor devices.

Further, the density distributions of radicals in the plasma are measured according to the first through sixth embodiments of the present invention, but the present invention is not restricted thereto, and it is possible to measure the density distribution of plasma itself.

The first through sixth embodiments of the present invention are described with respect to a gate etching process for forming Poly-Si gates, but the present invention is not restricted thereto, and can be applied to etching of other materials. Furthermore, in the case of a plasma CVD, since the radical density distribution and the temperature distribution of the substrate 1 influences the in-plane uniformity of the deposition rate or the in-plane uniformity of the film quality, a superior plasma CVD process is enabled by applying the present invention.

The first through sixth embodiments of the present invention are described with respect to a UHF-ECR apparatus, but the plasma source is not restricted to UHF-ECR, and the present invention can be applied to processing apparatuses utilizing other plasma sources such as ICP (inductively-coupled plasma) and CCP (capacitively-coupled plasma).

By utilizing the plasma etching apparatus of the present invention, the following plasma etching apparatuses and plasma etching methods are realized.

1. A plasma etching apparatus comprising:

a vacuum processing chamber for subjecting a substrate to plasma processing:

a substrate stage disposed in the vacuum processing chamber having a support surface for supporting the substrate;

a gas inlet for supplying processing gas into the vacuum processing chamber;

an electromagnetic wave supply means for supplying electromagnetic wave into the vacuum processing chamber;

a plurality of light receiving units for receiving plasma emission near a surface of the substrate from a side surface of the vacuum processing chamber, wherein the light receiving units are disposed so that the lengths of optical paths received by the respective light receiving units vary;

a plasma emission distribution measurement system disposed separately from the plurality of light receiving units; and

a means for computing a radical distribution in the plasma based on at least either the plasma emission distribution measurement system or the plurality of light receiving units; wherein

the plasma etching apparatus further includes a process for performing a plasma etching process in advance, a process for computing the radical distribution in the plasma during the process using the means for computing radical distribution and the plurality of light receiving units, and a process for measuring a CD shift distribution of the substrate subjected to plasma processing in the plasma etching process and storing the result thereof in a database;

a means for computing the radical distribution in the plasma using the plurality of light receiving units during a plasma etching process performed subsequent to said plasma etching process performed in advance; and

a means for controlling the plasma etching process conditions based on the data stored in the database.

2. The plasma etching apparatus according to aspect 1, wherein

an object for controlling the processing condition during the plasma etching process is either a composition and flow rate of the processing gas supplied through the plurality of gas inlets or a temperature distribution of the supporting surface of the substrate holder, or both.

3. The plasma etching apparatus according to aspect 1 or aspect 2, including a means for computing the radical distribution in the plasma using the plurality of light receiving units during a plasma etching process performed subsequent to said plasma etching process performed in advance, and a means for controlling the plasma etching process conditions based on the data stored in the database; wherein

the process for computing the radical distribution in the plasma and the process for controlling the plasma etching process conditions are performed at a timing selected from the following; per lot, per processing of the substrate, or per step of the plurality of etching steps; or the plasma etching process conditions is controlled immediately based on the computed result of the radical distribution in the plasma.

4. A plasma etching method for etching a substrate using a plasma etching apparatus comprising a vacuum processing chamber for subjecting the substrate to plasma processing; at least two gas supply sources for supplying processing gases to the vacuum processing chamber; gas inlets located at least at two locations for feeding processing gas to the vacuum processing chamber; an electromagnetic wave supplying means for supplying electromagnetic waves to the vacuum processing chamber; a plasma emission distribution measurement system for measuring the distribution of plasma emission near the surface of the substrate from a side surface; a means for computing the radical distribution in the plasma by the plasma emission distribution measurement system; and a means for controlling either a composition or a flow rate of processing gases fed through the two gas inlets based on the radical distribution computed in advance by the radical distribution computing means and the measurement result of the CD shift distribution; the method comprising the steps of

measuring a radical density distribution of at least one radical and a CD shift distribution during the etching process by performing at least two etching processes in advance with the flow rates of processing gases varied;

storing the conditions of the etching processes, the radical density distribution and the CD shift distribution in a database;

computing a relational expression of the radical density distribution for the at least one radical and the CD shift distribution;

computing a processing condition to realize a uniform CD shift using the relational expression; and

computing a control parameter of the etching process so as to realize the processing condition computed to realize a uniform CD shift;

wherein the etching process of the substrate is performed using the computed control parameter.

5. A plasma etching method for etching a substrate using a plasma etching apparatus comprising a vacuum processing chamber for subjecting the substrate to plasma processing; a substrate stage disposed in the vacuum processing chamber for holding the substrate and having formed therein a temperature control means for controlling the temperature of at least two locations; an electromagnetic wave supplying means for supplying electromagnetic waves to the vacuum processing chamber; a plasma emission distribution measurement system for measuring the distribution of plasma emission near the surface of the substrate from the side direction; a means for computing the radical distribution in the plasma by the plasma emission distribution measurement system; and a means for controlling the temperature of at least two locations of the substrate stage for the substrate based on the radical distribution computed in advance by the radical distribution computing means and the measurement result of the CD shift distribution; the method comprising the steps of

measuring a radical density distribution of at least one radical and a CD shift distribution during the etching process by performing at least two etching processes in advance with the flow rates of processing gases varied;

storing the conditions of the etching processes, the radical density distribution and the CD shift distribution in a database;

computing a relational expression of the radical density distribution for the at least one radical and the CD shift distribution; computing a processing condition to realize a uniform CD shift using the relational expression; and

computing a control parameter of the etching process so as to realize the processing condition computed to realize a uniform CD shift;

wherein the etching process of the substrate is performed using the computed control parameter.

6. A plasma etching method for etching a substrate using a plasma etching apparatus comprising a vacuum processing chamber for subjecting the substrate to plasma processing; gas inlets located at least at two locations for feeding processing gas into the vacuum processing chamber; a substrate stage disposed in the vacuum processing chamber for holding the substrate and having embedded therein a temperature control means for controlling the temperature of at least two locations; an electromagnetic wave supplying means for supplying electromagnetic waves to the vacuum processing chamber; a plasma emission distribution measurement system for measuring the distribution of plasma emission near the surface of the substrate from a side surface; a means for computing the radical distribution in the plasma by the plasma emission distribution measurement system; and a means for controlling a composition or a flow rate of processing gases fed through the two gas inlets and the temperature of at least two locations of the substrate stage for the substrate based on the radical distribution computed in advance by the radical distribution computing means and the measurement result of the CD shift distribution; the method comprising the steps of

measuring a radical density distribution of at least one radical and a CD shift distribution during the etching process by performing at least two etching processes in advance with the flow rates of processing gases varied;

storing the conditions of the etching processes, the radical density distribution and the CD shift distribution in a database;

computing a relational expression of the radical density distribution for the at least one radical and the CD shift distribution;

computing a processing condition to realize a uniform CD shift using the relational expression; and

computing a control parameter of the etching process so as to realize the processing condition computed to realize a uniform CD shift;

wherein the etching process of the substrate is performed using the computed control parameter.

7. The plasma etching method according to any one of the aforementioned 4 through 6, further comprising

measuring the radical density distribution of said at least one radical during the etching process; and

computing during the etching process the control parameter of the etching process so as to realize the processing condition computed to realize a uniform CD shift;

wherein the etching process of the substrate is performed using the computed control parameter.

8. The plasma etching method according to any one of the aforementioned 4 through 7, wherein

said control parameter for the etching process for realizing the processing condition computed so a to realize a uniform CD shift is at least either the compositions or flow rates of the processing gases fed from at least two locations, or the set temperatures of the temperature control means disposed at least at two locations for controlling the temperature distribution of the substrate.

What is claimed is:

1. A plasma etching method for etching a substrate using a plasma etching apparatus comprising:
a vacuum processing chamber for subjecting a substrate to plasma etching process;
a substrate stage disposed in the vacuum processing chamber having a support surface for supporting the substrate;
a plurality of gas inlets provided at an upper portion of the vacuum processing chamber for supplying processing gas into the vacuum processing chamber;
an electromagnetic wave supply means for supplying electromagnetic waves into the vacuum processing chamber;
a plurality of light receiving units for receiving plasma emission near a surface of the substrate from a side surface of the vacuum processing chamber, wherein the light receiving units are disposed so that the lengths of optical paths received by the respective light receiving units vary;
a plasma emission distribution measurement system disposed separately from the plurality of light receiving units for observing an emission intensity of a desired radical at a desired direction near the surface of the substrate;
a spectroscope for converting the plasma emission received via the plasma emission distribution measurement system and the plurality of light receiving units to emission spectral data;
a means for computing a radical distribution in the plasma during the plasma etching process using the emission spectral data obtained via the spectroscope;
a database for storing the radical distribution computed via the means for computing radical distribution and a CD shift distribution of the substrate obtained by the plasma etching process; and
a means for controlling a processing condition of etching using the radical distribution and the CD shift distribution stored in the database and a radical distribution computed via the means for computing the radical distribution during the plasma etching process;
the method comprising the steps of:
performing at least two plasma etching processes in advance with the composition or the flow rate of the processing gas varied, and computing the radical density distribution of at least one radical during the plasma etching process;
measuring the CD shift distribution of the substrate after the plasma etching process;
storing the condition of the plasma etching processes, the radical density distribution and the CD shift distribution in the database;
computing a relational expression of the radical density distribution of the at least one radical and the CD shift distribution of the substrate;
computing a processing condition to realize a uniform CD shift of the substrate; and
computing a control parameter of the etching process in order to realize the computed processing condition, so as to perform the plasma etching process of the substrate using the control parameter.

2. The plasma etching method according to claim 1, further comprising:
measuring the radical density distribution of at least one radical during the plasma etching process; and
computing the control parameter of the plasma etching process during the etching process in order to realize the computed processing condition for realizing a uniform CD shift of the substrate, so as to perform the plasma etching process of the substrate using the control parameter.

3. The plasma etching method according to claim 1, wherein the control parameter of the of the etching process for realizing the computed processing condition for realizing a uniform CD shift is at least either the composition or flow rate of the processing gas introduced through gas inlets provided at least at two locations or the temperature distribution of the substrate stage for controlling the temperature distribution of the substrate.

4. The plasma etching method according to claim 2, wherein the control parameter of the of the etching process for realizing the computed processing condition for realizing a uniform CD shift is at least either the composition or flow rate of the processing gas introduced through gas inlets provided at least at two locations or the temperature distribution of the substrate stage for controlling the temperature distribution of the substrate.
